(19) United States
(12) Patent Application Publication
(10) Pub. No.: US 2013/0307075 A1
(43) Pub. Date: Nov. 21, 2013

(54) CRYSTALLINE THIN-FILM TRANSISTORS AND METHODS OF FORMING SAME

(71) Applicant: INTERNATIONAL BUSINESS MACHINES CORPORATION, Armonk, NY (US)

(72) Inventors: Bahman Hekmatshoar-Tabari, Mount Kisco, NY (US); Devendra K. Sadana, Pleasantville, NY (US); Ghavam G. Shahidi, Round Ridge, NY (US); Davood Shahrjerdi, Ossining, NY (US)

(73) Assignee: INTERNATIONAL BUSINESS MACHINES CORPORATION, Armonk, NY (US)

(21) Appl. No.: 13/838,695

(22) Filed: Mar. 15, 2013

Related U.S. Application Data
(60) Provisional application No. 61/647,002, filed on May 15, 2012.

(51) Int. Cl. H01L 29/786; H01L 29/66

(52) U.S. Cl. CPC H01L 29/78654; H01L 29/66772
USPC 257/347; 438/164

(57) ABSTRACT

Thin film transistors containing a gate structure on a crystalline semiconductor material including a crystalline active channel layer are provided. The gate structure of the present disclosure includes an insulator stack of, from bottom to top, a hydrogenated non-crystalline semiconductor material layer portion and a hydrogenated non-crystalline silicon nitride portion. Doped crystalline semiconductor source/drain regions are located on opposing sides of the gate structure and on surface portions of the crystalline semiconductor material.

### RELATED APPLICATION

The present application claims benefit of U.S. Provisional Application Ser. No. 61/647,002, filed on May 15, 2012, the entire content of which is incorporated herein by reference.

### BACKGROUND

The present disclosure relates to semiconductor structures and methods of forming the same. More particularly, the present disclosure relates to crystalline thin film transistors and methods of forming the same.

Mainstream thin film transistor (TFT) devices are comprised of amorphous or polycrystalline semiconductor materials as the active channel materials. One reason for using such semiconductor materials as the active channel material is that amorphous and polycrystalline semiconductor materials allow for large area and low cost deposition which is particularly suitable for low-cost substrates such as glass or flexible plastic. However, the performance of these devices (particularly mobility and therefore drive current and switching speed) is limited by the non-crystalline nature of the semiconductor active channel material. High performance devices may be achieved by crystalline semiconductors; however, the high processing temperatures typically required for processing crystalline semiconductor devices is not compatible with low-cost substrates used for amorphous and polycrystalline devices. In addition, crystalline semiconductors are conventionally processed on a wafer-scale basis, rather than by large-area processing as used for amorphous and polycrystalline devices. Therefore, the industrial infrastructure used for processing of mainstream thin-film devices cannot be used for processing crystalline devices.

### SUMMARY

Thin film transistors containing a gate structure on a crystalline semiconductor material including a crystalline active channel layer are provided. The gate structure of the present disclosure includes an insulator stack of, from bottom to top, a hydrogenated non-crystalline semiconductor material layer portion and a hydrogenated non-crystalline silicon nitride portion. Doped crystalline semiconductor source/drain regions are located on opposing sides of the gate structure and on surface portions of the crystalline semiconductor material.

In one aspect of the present disclosure, semiconductor structures are provided that include an active device region comprising a crystalline semiconductor material located on a surface of an insulating substrate. The structures further include a gate structure located on a first surface portion of the active device region. In accordance with the present disclosure, the gate structure includes, from bottom to top, a hydrogenated non-crystalline semiconductor material layer portion, a hydrogenated non-crystalline silicon nitride portion and an electrode material portion.

In another aspect of the present disclosure, methods of forming a semiconductor structure are provided. In one embodiment, the method includes forming a gate structure on a first surface portion of a crystalline semiconductor material, wherein the gate structure comprises, from bottom to top, a hydrogenated non-crystalline semiconductor material layer portion, a hydrogenated non-crystalline silicon nitride portion and an electrode material portion. Next, a first doped crystalline semiconductor material portion is epitaxially grown on one side of the gate structure and in direct contact with a second surface portion of the crystalline semiconductor material, and a second doped crystalline semiconductor material portion is epitaxially grown on another side of the gate structure and in direct contact with a third surface portion of the crystalline semiconductor material.

In a further embodiment, the method includes forming a source region comprising an epitaxial first doped crystalline semiconductor material portion on a surface portion of a crystalline semiconductor material, and a drain region comprising an epitaxial second doped crystalline semiconductor material portion on another surface portion of the crystalline semiconductor material, wherein the source region and the drain region are disjoined from each other. Next, a gate structure is formed on a further surface portion of a crystalline semiconductor material and between the source region and the drain region, wherein the gate structure comprises, from bottom to top, a hydrogenated non-crystalline semiconductor material layer portion, a hydrogenated non-crystalline silicon nitride portion and an electrode material portion.

### BRIEF DESCRIPTION OF THE DRAWINGS

FIG. 1 is a pictorial representation (through a cross sectional view) illustrating an initial structure including a blanket layer of a crystalline semiconductor material located on a surface of an insulating substrate that may be used in accordance with an embodiment of the present disclosure.

FIG. 2 is a pictorial representation (through a cross sectional view) illustrating the structure of FIG. 1 after defining an active device region within the blanket layer of crystalline semiconductor material.

FIG. 3 is a pictorial representation (through a cross sectional view) illustrating the structure of FIG. 2 after forming a gate structure on a surface of the active device region, wherein the gate structure includes, from bottom to top, a hydrogenated non-crystalline semiconductor material layer portion, a hydrogenated non-crystalline silicon nitride portion and an electrode material portion.

FIG. 4 is a pictorial representation (through a cross sectional view) illustrating the structure of FIG. 3 after forming a doped semiconductor material layer comprising doped crystalline semiconductor material layer portions and adjoining doped non-crystalline semiconductor material layer portions.

FIG. 5 is a pictorial representation (through a cross sectional view) illustrating the structure of FIG. 4 after removing the doped non-crystalline semiconductor material layer portions selective to the doped crystalline semiconductor material layer portions.

FIG. 6 is a pictorial representation (through a cross sectional view) illustrating the structure of FIG. 5 after formation of a passivation material thereon.

FIG. 7 is a pictorial representation (through a cross sectional view) illustrating the structure of FIG. 6 after formation of metal contacts within the passivation material.

FIG. 8 is a pictorial representation (through a cross sectional view) illustrating the structure of FIG. 1 after forming a source region comprising a doped first crystalline semiconductor material layer portion, and a drain region comprising a doped second crystalline semiconductor material layer portion on a topmost surface of the crystalline semiconductor material in accordance with an embodiment of the present disclosure.

FIG. 9 is a pictorial representation (through a cross sectional view) illustrating the structure of FIG. 8 after defining an active device region within the crystalline semiconductor material.

FIG. 10 is a pictorial representation (through a cross sectional view) illustrating the structure of FIG. 9 after forming a gate structure on an uppermost surface of the active device region and an uppermost surface of the source region and drain region, wherein the gate structure includes, from bottom to top, a hydrogenated non-crystalline semiconductor material layer portion, a hydrogenated non-crystalline silicon nitride portion and an electrode material portion.

FIG. 11 is a pictorial representation (through a cross sectional view) illustrating the structure of FIG. 3 after forming a dielectric spacer material thereon in accordance with another embodiment of the present disclosure.

FIG. 12 is a pictorial representation (through a cross sectional view) illustrating the structure of FIG. 11 after etching the dielectric spacer material forming dielectric spacers.

FIG. 13 is a pictorial representation (through a cross sectional view) illustrating the structure of FIG. 12 after forming a source region comprising a doped first crystalline semiconductor material layer portion, and a drain region comprising a doped second crystalline semiconductor material layer portion on a topmost surface of the active device region.

### DETAILED DESCRIPTION

The present disclosure, which relates to thin film transistors including a crystalline semiconductor channel region and methods of forming the same, will now be described in greater detail by referring to the following discussion and drawings that accompany the present application. It is noted that the drawings of the present application are provided for illustrative purposes and, as such, they are not drawn to scale. In the drawings and description that follows, like elements are described and referred to by like reference numerals.

In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced with viable alternative process options without these specific details. In other instances, well-known structures or processing steps have not been described in detail in order to avoid obscuring the various embodiments of the present disclosure.

The term “crystalline” is used throughout the present disclosure to denote a single crystalline material, a multi-crystalline material or a polycrystalline material. Typically, the crystalline semiconductor material that is employed in the present disclosure is comprised of a single crystalline semiconductor material. The term “non-crystalline” is used throughout the present disclosure to denote an amorphous, nano-crystalline or micro-crystalline material. Typically, the non-crystalline semiconductor material that is employed in the present disclosure is amorphous. The term “intrinsic” is used throughout the present disclosure to denote a semiconductor material that contains no doping atoms therein or alternatively a semiconductor material in which the concentration of dopant atoms therein is less than 10¹⁵ atoms/cm³.

In the present disclosure, a crystalline semiconductor material is used as the active device region of a thin film transistor (TFT). At least a portion of the active device region of the present disclosure functions as a channel of the TFT. If the channel is p-type, the highly-doped source/drain regions are n-type, and vice versa. In the present disclosure, a gate insulator stack comprised of a thin hydrogenated non-crystalline semiconductor material layer portion, i.e., hydrogenated amorphous Si (a-Si:H), and a hydrogenated non-crystalline silicon nitride portion, i.e., hydrogenated amorphous silicon nitride (a-SiNₓ:H), is formed on a portion of the active device region. In conventional amorphous and poly-Si TFTs, a-SiNₓ:H is typically used as the gate dielectric as it results in a better channel/dielectric interface quality (having a lower density of interface states) compared to hydrogenated amorphous oxide (a-SiOₓ:H). However, a-SiNₓ:H results in a poor interface in case of crystalline Si. Therefore, a thin hydrogenated non-crystalline semiconductor material layer portion (i.e., a-Si:H) is used in the present disclosure to improve the interface quality by reducing the density of interface states. This is because the interface between a hydrogenated non-crystalline semiconductor material such as, for example, a-Si:H, and a crystalline semiconductor material, such as, for example, single crystalline Si, has a low density of interface states, and the interface between a hydrogenated non-crystalline semiconductor material (i.e., a-Si:H) and hydrogenated non-crystalline silicon nitride (i.e., a-SiNₓ:H) also has a low density of interface states, and therefore a direct interface between the crystalline semiconductor material and hydrogenated non-crystalline silicon nitride, which would result in a high density of interface states, is avoided. In some embodiments, high-k dielectrics such as Al₂O₃ and HfO₂ may be used instead of the disclosed gate insulator stack, typically using atomic layer deposition (ALD).

Referring first to FIGS. 1-5, there are illustrated one method of the present disclosure which can be used in forming a thin film transistor including a crystalline semiconductor channel. In the embodiment illustrated within FIGS. 1-5, the gate structure of the thin film transistor is self-aligned to the corresponding source/drain regions that are formed upon the active device region, which functions as the channel region of the disclosed structures. By “self-aligned” it is meant that the gate structure has sidewall surfaces that do not extend upon any portion of the source/drain regions of the structure.

Referring first to FIG. 1, there is illustrated an initial structure including a blanket layer of a crystalline semiconductor material 10 located on a surface of an insulating substrate 8 which can be used in accordance with an embodiment of the present disclosure.

The insulating substrate 8 that can be employed in the present disclosure includes, but is not limited to, an oxide, a nitride, an oxynitride or a multilayered stack. In one embodiment, the insulating substrate 8 is comprised of a semiconductor oxide and/or a semiconductor nitride. An example of a semiconductor oxide that can be employed as the insulating substrate 8 includes silicon dioxide, while an example of a semiconductor nitride is silicon nitride. The thickness of the insulating substrate 8 can be from 5 nm to 500 nm. Other thicknesses that are lesser than, or greater than, the aforementioned thickness range can also be employed as the thickness of the insulating substrate 8. In some embodiments, a handle substrate (not shown in the drawings) such as, for example, a semiconductor substrate, glass, plastic or metal foil can be located directly beneath the insulating substrate 8. In embodiments where the handle substrate is insulating, a separate insulating material is not needed since the insulating handle substrate can serve as the insulating substrate 8.

In one embodiment, the insulating substrate 8 is a component of a semiconductor-on-insulator substrate. In this embodiment, the crystalline semiconductor material 10 can be the topmost semiconductor layer of the semiconductor-on-insulator substrate. In another embodiment, the insulating substrate 8 is formed on a surface of a handle substrate by deposition or a thermal growth technique and then an exposed surface of the insulating substrate 8 is bonded to a crystalline semiconductor layer which can be used as the crystalline semiconductor material 10.

In one embodiment, the crystalline semiconductor material 10 that can be employed in the present disclosure can be an III-V compound semiconductor which includes at least one element from Group IIIA (i.e., Group 13) of the Periodic Table of Elements and at least one element from Group VA (i.e., Group 15) of the Periodic Table of Elements. The range of possible formulae for suitable III-V compound semiconductors that can be used in the present disclosure is quite broad because these elements can form binary (two elements, e.g., gallium (III) arsenide (GaAs)), ternary (three elements, e.g., indium gallium arsenide (InGaAs)) and quaternary (four elements, e.g., aluminum gallium indium phosphide (AlInGaP)) alloys.

In another embodiment of the present disclosure, the crystalline semiconductor material 10 can be a semiconductor material having the formula Si_{y}Ge_{1-y} wherein y is 0≦y≦1. In some embodiments, in which y is 1, the crystalline semiconductor material 10 can be comprised entirely of Si. In another embodiment, in which y is 0, the crystalline semiconductor material 10 can be comprised entirely of Ge. In yet another embodiment and when y is other than 0 or 1, the crystalline semiconductor material 10 can be comprised entirely of a SiGe alloy.

In yet another embodiment of the present disclosure, the crystalline semiconductor material 10 can be a semiconductor material comprised of SiC.

In some embodiments of the present disclosure, the crystalline semiconductor material 10 may include nitrogen, oxygen, fluorine, deuterium, chlorine or any combination thereof. When present, the concentration of the aforementioned species can be from 1 atomic % to 10 atomic percent. Other concentrations that are lesser than, or greater than, the aforementioned concentration range can also be present.

In some embodiments, and as shown in FIG. 1, the entirety of the crystalline semiconductor material 10 is of a first conductivity type, i.e., either p-type or n-type. As used herein, “p-type” refers to the addition of impurities to an intrinsic semiconductor that creates deficiencies of valence electrons (i.e., holes). In a Si-containing semiconductor material, examples of p-type dopants, i.e., impurities, include but are not limited to, boron, aluminum, gallium and indium. In one embodiment, in which the first conductivity type of the crystalline semiconductor material 10 of the present disclosure is p-type, the p-type dopant is present in a concentration ranging from 1×10⁹ atoms/cm³ to 1×10²⁰ atoms/cm³. In another embodiment, in which the first conductivity type of the crystalline semiconductor material 10 of the present disclosure is p-type, the p-type dopant is present in a concentration ranging from 1×10¹⁴ atoms/cm³ to 1×10¹⁹ atoms/cm³. As used herein, “n-type” refers to the addition of impurities that contributes free electrons to an intrinsic semiconductor. In a Si-containing semiconductor, examples of n-type dopants, i.e., impurities, include but are not limited to, antimony, arsenic and phosphorous. In one embodiment, in which the first conductivity type of the crystalline semiconductor material 10 of the present disclosure is n-type, the n-type dopant is present in a concentration ranging from 1×10⁹ atoms/cm³ to 1×10²⁰ atoms/cm³. In another embodiment, in which the first conductivity type of the crystalline semiconductor material 10 of the present disclosure is n-type, the n-type dopant is present in a concentration ranging from 1×10¹⁴ atoms/cm³ to 1×10¹⁹.

The dopant concentration of the first conductivity type within the crystalline semiconductor material 10 of the present disclosure may be graded or uniform. By “uniform” it is meant that the dopant concentration of first conductivity type is the same throughout the entire thickness of the crystalline semiconductor material 10. For example, a crystalline semiconductor material 10 having a uniform dopant concentration of the first conductivity type may have the same dopant concentration at the upper surface and bottom surface of the semiconductor material, as well as the same dopant concentration at a central portion of the semiconductor material between the upper surface and the bottom surface of the crystalline semiconductor material 10. By “graded” it is meant that the dopant concentration of the first conductivity type varies throughout the thickness of the crystalline semiconductor material 10. For example, a crystalline semiconductor material 10 having a graded dopant concentration may have an upper surface with a greater dopant concentration of the first conductivity type than the bottom surface of the crystalline semiconductor material 10, and vice versa.

In some embodiments, the first conductivity type can be introduced during the growth of the crystalline semiconductor material that can be used as element 10 of the present disclosure. Alternatively, the conductivity type can be introduced into an intrinsic crystalline semiconductor material by utilizing ion implantation, and/or gas phase doping and the doped crystalline semiconductor material can be employed as the crystalline semiconductor material 10. The thickness of the crystalline semiconductor material 10 can be from 3 nm to 3 μm. Other thicknesses that are lesser than, or greater than, the aforementioned thickness range can also be employed for the thickness of the crystalline semiconductor material 10.

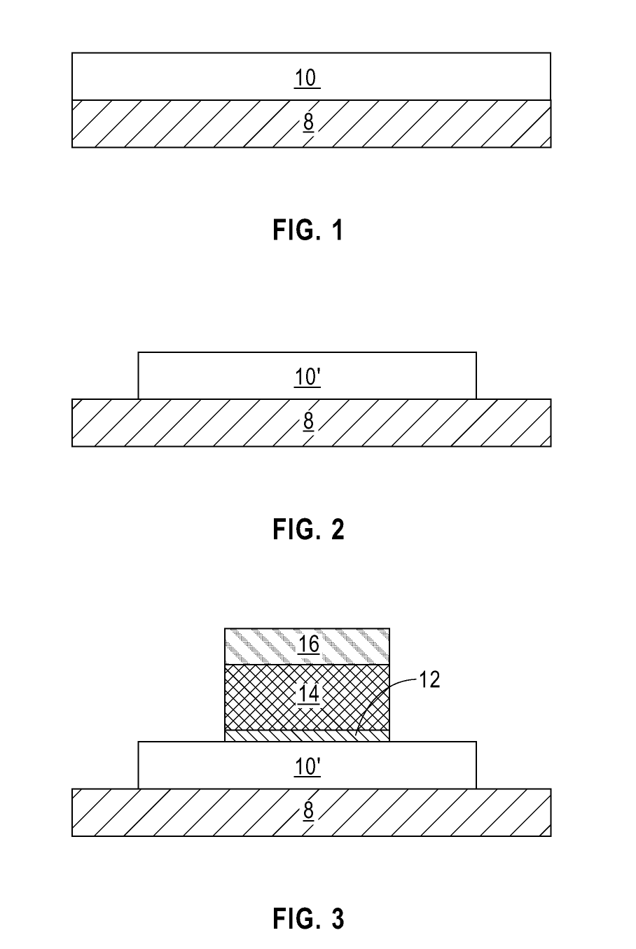

Referring now to FIG. 2, and in one embodiment of the present disclosure, there is illustrated the structure of FIG. 1 after defining an active device region 10′ within the blanket layer of crystalline semiconductor material 10. The definition of the active device region 10′ (which comprises a remaining portion of the crystalline semiconductor material 10) in the blanket layer of crystalline semiconductor material 10 can be performed by lithography and etching. Lithography includes forming a photoresist material (not shown) on an exposed surface of the blanket layer of crystalline semiconductor material 10, exposing the photoresist material to a desired pattern of radiation, and developing the photoresist material utilizing a conventional resist developer. The desired pattern that is formed into the photoresist material can be in the form of a via or a trench. The etching step, which transfers the pattern from the patterned photoresist into the blanket layer of crystalline semiconductor material 10, can include dry etching (i.e., reactive ion etching, ion beam etching, or plasma etching), wet chemical etching, or a combination thereof. In one embodiment of the present disclosure, a selective etch process (typically a dry etch) is used to pattern the blanket layer of crystalline semiconductor material 10. After pattern transfer, the patterned photoresist is typically removed from the structure utilizing a conventional stripping process such as, for example, ashing. At least a portion of the active device region 10′ can function as the active channel of the TFT of the present disclosure.

In some embodiments of the present disclosure, the structure shown in FIG. 2 can be formed by bonding a pre-patterned crystalline semiconductor material directly onto the insulating substrate 8. In some embodiments of the present disclosure, the definition of the active device region 10′ in the blanket layer of crystalline semiconductor material 10 can be delayed until after forming the gate structure or after forming the source/drain regions.

Referring to FIG. 3, and in one embodiment of the present disclosure, there is illustrated the structure of FIG. 2 after forming a gate structure on a surface of the active device region 10′, wherein the gate structure includes, from bottom to top, a hydrogenated non-crystalline semiconductor material layer portion 12, a hydrogenated non-crystalline silicon nitride portion 14 and an electrode material portion 16. As shown, each element (i.e., 12, 14, and 16) of the gate structure has an outermost edge that defines a sidewall of the gate structure and the outermost edges of each element of the gate structure are vertically coincident to each other.

The hydrogenated non-crystalline semiconductor material layer portion 12 of the gate structure may comprise a same or different semiconductor material as that of the active device region 10′. In one embodiment, the hydrogenated non-crystalline semiconductor material layer portion 12 of the gate structure has a formula Si_{z}Ge_{1-z} wherein z is 0≦z≦1. As such, the hydrogenated non-crystalline semiconductor material layer portion 12 of the gate structure may comprise Si (when z is 1), Ge (when z is 0), or a SiGe (when z is other than 1, or 0). In one embodiment, the hydrogenated non-crystalline semiconductor material layer portion 12 comprises hydrogenated amorphous silicon (a-Si:H).

In accordance with the present disclosure, the hydrogenated non-crystalline semiconductor material layer portion 12 contains from 5 atomic % to 40 atomic % hydrogen therein. In one embodiment, the hydrogenated non-crystalline semiconductor material layer portion 12 contains from 10 atomic % to 25 atomic % hydrogen therein. In yet another embodiment, the hydrogenated non-crystalline semiconductor material layer portion 12 contains from 20 atomic % to 30 atomic % hydrogen therein.

In some embodiments of the present disclosure, the hydrogenated non-crystalline semiconductor material layer portion 12 can contain C therein. When present, C can be present in a concentration from 0 atomic % to 50 atomic %. In some embodiments, the hydrogenated non-crystalline semiconductor material layer portion 12 can contain from 0 atomic % to 25 atomic % carbon therein. The carbon impurity can be added by way of either a source gas that includes carbon, or by introducing a carbon source gas into the gas mixture that is employed in the present disclosure for forming the hydrogenated non-crystalline semiconductor material layer portion 12.

In some embodiments of the present disclosure, the hydrogenated non-crystalline semiconductor material layer portion 12 may include nitrogen, oxygen, fluorine, deuterium, chlorine or any combination thereof. When present, the concentration of the aforementioned species can be from 1 atomic % to 10 atomic percent. Other concentrations that are lesser than, or greater than, the aforementioned concentration range can also be present.

The hydrogenated non-crystalline semiconductor material layer portion 12 is typically non-doped. However, in some embodiments a dopant, such as described herein below for the doped semiconductor material used in forming the source/drain regions of the TFTs of the present disclosure, can be present within the hydrogenated non-crystalline semiconductor material layer portion 12. When present, the concentration of the dopant atom in the hydrogenated non-crystalline semiconductor material layer portion 12 is within the range mentioned herein below for the doped semiconductor material, and it can be introduced using one of the dopants also mentioned herein below with respect to doped semiconductor material. The thickness of the hydrogenated non-crystalline semiconductor material layer portion 12 may range from 2 nm to 100 nm. In another embodiment, the thickness of the hydrogenated non-crystalline semiconductor material layer portion 12 ranges from 5 nm to 15 nm.

The hydrogenated non-crystalline semiconductor material layer portion 12 can be formed as a blanket layer of hydrogenated non-crystalline semiconductor material atop the entire exposed uppermost surface of the active device region 10′. In one embodiment, a blanket layer of hydrogenated non-crystalline semiconductor material can be formed by plasma enhanced chemical vapor deposition (PECVD). PECVD is a deposition process used to deposit films from a gas state (vapor) to a solid state on a deposition substrate. Chemical reactions are involved in the process, which occur after creation of a plasma of the reacting gases. A plasma is any gas in which a significant percentage of the atoms or molecules are ionized. Fractional ionization in plasmas used for deposition and related materials processing varies from about 10⁻⁴ in capacitive discharge plasmas to as high as 5-10% in high density inductive plasmas. Processing plasmas are typically operated at pressures of a few millitorr to a few ton, although arc discharges and inductive plasmas can be ignited at atmospheric pressure. In some embodiments, the plasma is created by RF (AC) frequency, such as a radio frequency induced glow charge, or DC discharge between two electrodes, the space between which is filled with the reacting gases. In one example, a PECVD device employs a parallel plate chamber configuration.

In other embodiments, a hot-wire chemical vapor deposition (HWCVD) process can be used in forming the blanket layer of hydrogenated non-crystalline semiconductor material. In yet another embodiment, sputtering or atomic layer deposition (ALD) can be used in forming the blanket layer of hydrogenated non-crystalline semiconductor material. The blanket layer of hydrogenated non-crystalline semiconductor material can be formed at a temperature close to 200° C., with highest quality films typically grown at temperatures in the range of 150° C.-250° C., however temperatures in the range from room-temperature (i.e., 20° C.) up to 450° C. may be used.

In one embodiment, the source gas used to form the blanket layer of hydrogenated non-crystalline semiconductor material may comprise a Si-containing precursor, such as, for example a silane and a disilane and/or a germanium-containing precursor such as, for example, a germane, GeH₄. In some embodiments, Si-containing and Ge-containing precursors can be used in forming the blanket layer of hydrogenated non-crystalline semiconductor material. Other gases including a carbon source such, as for example, CH₄ may be used. In some embodiments, ammonia (NH₃), nitrous oxide (N₂O) or other gas sources may be used for nitrogen containing layers. Carbon dioxide (CO₂), N₂O or O₂ may be used to provide oxygen for oxygen containing layers. A carrier gas such as hydrogen (H₂), deuterium (D₂) helium (He) or argon (Ar) may be used for any or all of the layers. The carrier gas may be pre-mixed with the gas sources or flowed simultaneously with the gas source at the time of growth.

In one embodiment, a gas mixture including a ratio of hydrogen to source gas of from greater than 5:1 can be used in forming the blanket layer of hydrogenated non-crystalline semiconductor material. In another embodiment, the ratio of hydrogen to source gas that can be used ranges from 5:1 to 1000:1. For example, growth of silicon is possible at temperatures as low as 150° C. with ratios of hydrogen to silane (SiH₄) ranging from 5:1 to 20:1.

Next, a blanket layer of a hydrogenated non-crystalline silicon nitride (which will be subsequently patterned into the hydrogenated non-crystalline silicon nitride portion 14) is formed on an exposed surface of the blanket layer of hydrogenated non-crystalline semiconductor material. In one embodiment, the blanket layer of hydrogenated non-crystalline silicon nitride is hydrogenated amorphous silicon nitride (a-SiNₓ:H).

In accordance with the present disclosure, the blanket layer of hydrogenated non-crystalline silicon nitride contains from 5 atomic % to 40 atomic % hydrogen therein. In one embodiment, the blanket layer of hydrogenated non-crystalline silicon nitride contains from 10 atomic % to 25 atomic % hydrogen therein. In yet another embodiment, the blanket layer of hydrogenated non-crystalline silicon nitride contains from 20 atomic % to 30 atomic % hydrogen therein.

The blanket layer of hydrogenated non-crystalline silicon nitride contains nitrogen in a concentration from 1 atomic % to 20 atomic %. In some embodiments, the blanket layer of hydrogenated non-crystalline silicon nitride can contain from 1 atomic % to 10 atomic % nitrogen therein. The nitrogen impurity can be added by way of either a source gas that includes nitrogen, or by introducing a nitrogen source gas into the gas mixture that is employed in the present disclosure for forming the blanket layer of hydrogenated non-crystalline silicon nitride.

The blanket layer of hydrogenated non-crystalline silicon nitride is formed utilizing one of the processes mentioned above for forming the blanket layer of hydrogenated non-crystalline semiconductor material. The source gas used to form the blanket layer of hydrogenated non-crystalline silicon nitride comprises a Si-containing precursor, such as, for example a silane and a disilane. Ammonia (NH₃), nitrous oxide (N₂O) or other nitrogen-containing gas sources may be used for introducing nitrogen within the blanket layer of hydrogenated non-crystalline silicon nitride.

The blanket layer of hydrogenated non-crystalline silicon nitride is typically non-doped. The thickness of the blanket layer of hydrogenated non-crystalline silicon nitride may range from 2 nm to 100 nm. In another embodiment, the thickness of the blanket layer of hydrogenated non-crystalline silicon nitride ranges from 5 nm to 15 nm.

It should be noted that although the blanket layer of hydrogenated non-crystalline semiconductor material and hydrogenated non-crystalline silicon nitride are described and illustrated as single layers, the blanket layer of hydrogenated non-crystalline semiconductor material may include a multilayered stack comprising various layers of semiconductor materials (which may be the same or different from each other), and the blanket layer of hydrogenated non-crystalline silicon nitride may include a multilayered stack comprising various hydrogenated non-crystalline silicon nitride layers having a same or different hydrogen and/or nitrogen content.

After forming the material stack of blanket layers of hydrogenated non-crystalline semiconductor material and hydrogenated non-crystalline silicon nitride, an electrode material portion 16 can be formed on an uppermost surface of the layer of hydrogenated non-crystalline silicon nitride. The electrode material portion 16 can be formed prior to, or after, patterning of the blanket layer of hydrogenated non-crystalline semiconductor material and hydrogenated non-crystalline silicon nitride. The electrode material portion 16 can be comprised of a conductive material including, for example, a doped Si-containing material, a conductive metal, a conductive metal alloy comprising at least two conductive metals, a conductive metal nitride, a transparent conductive oxide and/or a conductive metal silicide. Examples of conductive metals that can be used include, for example, Cu, W, Pt, Al, Pd, Ru, Ni, and Ir. The electrode material portion 16 can have a thickness from 1 nm to 1000 nm. Other thicknesses that are lesser than, or greater than, the aforementioned thickness range can also be employed as the thickness for the electrode material portion 16.

In some embodiments, the electrode material portion 16 can be formed using a deposition process including, for example, chemical vapor deposition, plasma enhanced chemical vapor deposition, sputtering, chemical solution deposition, or plating. Metal silicides can be formed utilizing any conventional silicidation process that is well known to those skilled in the art. In some embodiments, the conductive material can be patterned by lithography and etching as described hereinabove.

In some embodiments, an etch mask is formed first, then the blanket layers of hydrogenated non-crystalline semiconductor material and hydrogenated non-crystalline silicon nitride are patterned, and then the etch mask is replaced with the electrode material portion 16.

In either embodiment, the exposed portions of the blanket layers of hydrogenated non-crystalline semiconductor material and hydrogenated non-crystalline silicon nitride that are not protected by either the electrode material portion or, if used, the etch mask, are etched selective to the underlying active device region 10′. In one embodiment, a single etch may be used to remove exposed portions of both the blanket layers of hydrogenated non-crystalline semiconductor material and hydrogenated non-crystalline silicon nitride which are not protected by the electrode material portion 16 or the etch mask. In another embodiment, two separate etching steps can be used to remove the blanket layers of hydrogenated non-crystalline semiconductor material and hydrogenated non-crystalline silicon nitride which are not protected by the electrode material portion 16 or the etch mask.

The etch or etches that can be used in this embodiment of the present disclosure may include for example, a dry etch process such as, for example, reactive ion etching, plasma etching or ion beam etching. Alternatively, a chemical wet etch can be employed. In one embodiment, the exposed portions of the blanket layers of hydrogenated non-crystalline semiconductor material and hydrogenated non-crystalline silicon nitride not protected by the electrode material portion 16 or etch mask can be removed by CF₄, SF₆, SF₆/O₂ or CCl₂F₂/O₂ plasma.

After etching of the blanket layers of hydrogenated non-crystalline semiconductor material and hydrogenated non-crystalline silicon nitride not protected by the electrode material portion 16 or etch mask, and, if needed replacement of the etch mask with an electrode material portion 16, a gate structure is formed that comprises from bottom to top, a hydrogenated non-crystalline semiconductor material layer portion 12 (i.e., a remaining portion of the blanket layer of hydrogenated non-crystalline semiconductor material), a hydrogenated non-crystalline silicon nitride portion 14 (i.e., a remaining portion of the blanket layer of hydrogenated non-crystalline silicon nitride) and electrode material portion 16.

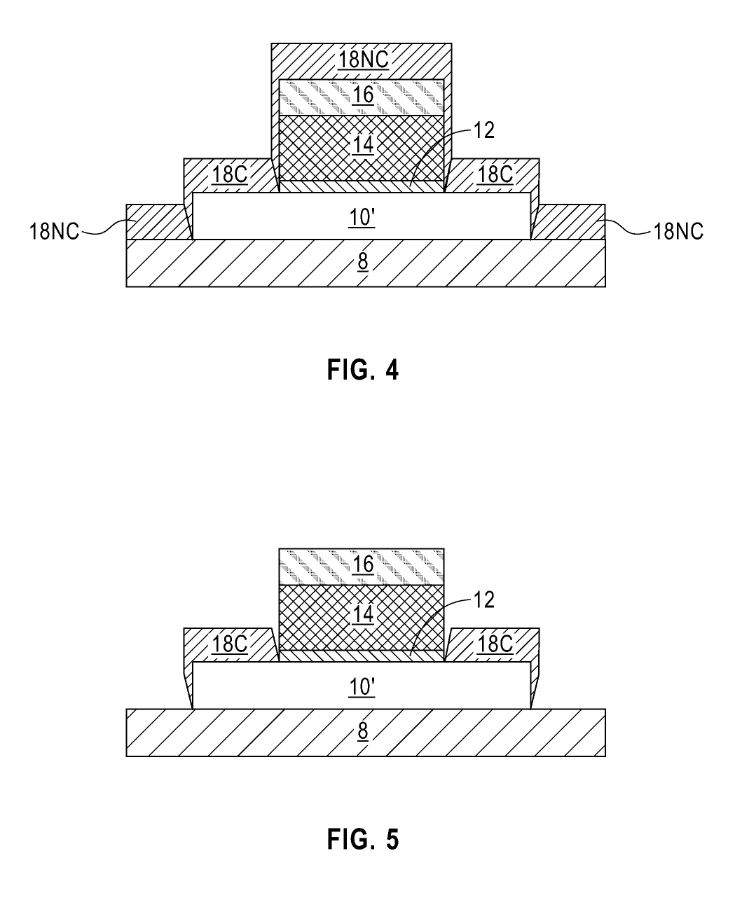

Referring now to FIG. 4, there is illustrated the structure of FIG. 3 after forming a doped semiconductor material layer comprising doped crystalline semiconductor material layer portions 18C and adjoining doped non-crystalline semiconductor material layer portions 18NC. In some embodiments, the doped semiconductor material including the crystalline and non-crystalline portions can be hydrogenated. It is noted that the crystalline portions and the non-crystalline portions are simultaneously formed and are thus of unitary construction. Also, the doped crystalline semiconductor material layer portions 18C are formed atop crystalline surfaces, while the adjoining doped non-crystalline semiconductor material layer portions 18NC are formed atop non-crystalline surfaces. The dopant within the doped semiconductor layer is of a second conductivity type that is opposite from the conductivity type of the crystalline channel (i.e., active device region 10′). In some embodiments, and as illustrated in FIG. 4, a portion of the doped crystalline semiconductor material layer portion extends onto sidewall surfaces of the active device region 10′.

In accordance with the present disclosure and when hydrogen is present in the doped semiconductor material, the doped semiconductor material layer may contain from 5 atomic % to 40 atomic % hydrogen therein. In one embodiment, the doped semiconductor material layer may contain from 10 atomic % to 25 atomic % hydrogen therein. In yet another embodiment, the doped semiconductor material layer may contain from 20 atomic % to 30 atomic % hydrogen therein.

The doped semiconductor material layer comprising doped crystalline semiconductor material layer portions 18C and adjoining doped non-crystalline semiconductor material layer portions 18NC is formed utilizing an epitaxial growth deposition process. The term “epitaxial growth and/or deposition” means the growth of a semiconductor material on a deposition surface of a semiconductor material, in which the semiconductor material being grown has the same (or nearly the same) crystalline characteristics as the semiconductor material of the deposition surface. Therefore, in places in which the doped semiconductor material layer is grown on exposed surfaces of the active device region 10′ comprising crystalline semiconductor material 10, a doped crystalline semiconductor material layer 18C is formed, while in other places in which the doped semiconductor material layer is grown a non-crystalline material, such as the insulator substrate 8, and the gate structure (12, 14, 16), a doped non-crystalline semiconductor material layer portion 18NC is formed. It is noted that each non-crystalline portion 18NC of the doped semiconductor material layer comprises the same material and nearly the same or the same doping concentration as that of the crystalline portion 18C of the doped semiconductor material layer; however, if present, the hydrogen content and/or distribution, and the doping efficiency (percentage of activated doping species) in the non-crystalline portions 18NC and the crystalline portion 18C may be different.

In accordance with an embodiment of the present disclosure, the doped semiconductor material layer (including crystalline portions 18C and non-crystalline portions 18NC) is epitaxially grown at a temperature of less than 500° C. using a gas mixture that includes a source gas, optionally hydrogen and a dopant gas. The lower temperature limit for the epitaxial growth of the doped semiconductor material layer is generally 100° C. In some embodiments, the doped semiconductor material layer can be epitaxially grown at a temperature from 150° C. to 300° C. In other embodiments, the doped semiconductor material layer can be epitaxially grown at a temperature from 150° C. to 250° C. The temperatures disclosed herein for the epitaxial growth is at the surface of the substrate in which the epitaxial semiconductor material layer is formed.

In one embodiment of the present disclosure, the doped semiconductor material layer (including crystalline portions 18C and non-crystalline portions 18NC) is epitaxially grown utilizing plasma enhanced chemical vapor deposition (PECVD). In one example, a PECVD device employs a parallel plate chamber configuration. In other embodiments, a hot-wire chemical vapor deposition process can be used in forming the doped semiconductor material layer.

In one embodiment, the source gas used to form the doped semiconductor material layer (including crystalline portions 18C and non-crystalline portions 18NC) may comprise a Si-containing precursor, such as, for example a silane and a disilane and/or a germanium-containing precursor such as, for example, a germane, GeH₄. In some embodiments, Si-containing and Ge-containing precursors can be used in forming the doped semiconductor material layer. Other gases including a carbon source such, as for example, CH₄ may be used.

In one embodiment and to provide epitaxial growth of a doped hydrogenated semiconductor material layer (including crystalline portions 18C and non-crystalline portions 18NC), a gas mixture including a ratio of hydrogen to source gas of from greater than 5:1 can be used. In another embodiment, the ratio of hydrogen to source gas that can be used ranges from 5:1 to 1000:1. For example, epitaxial growth of silicon is possible at temperatures as low as 150° C. with ratios of hydrogen to silane (SiH₄) ranging from 5:1 to 20:1.

The dopant gas that can be present in the epitaxial growth process provides the conductivity type, either n-type or p-type, to the doped semiconductor material layer (including crystalline portion 18C and non-crystalline portions 18NC). When a doped semiconductor material layer of an n-type conductivity is to be formed, the dopant gas includes at least one n-type dopant, e.g., phosphorus or arsenic. For example, when phosphorus is the n-type dopant, the dopant gas can be phosphine (PH₃), and when arsenic is the n-type dopant, the dopant gas can be arsine (AsH₃). In one example, when the conductivity type dopant is n-type, the dopant gas include phosphine gas (PH₃) present in a ratio to silane (SiH₄) ranging from 0.01% to 10%. In another example, when the conductivity type dopant is n-type, the dopant gas include phosphine gas (PH₃) present in a ratio to silane (SiH₄) ranging from 0.1% to 2%.

When a doped semiconductor material layer (including crystalline portions 18C and non-crystalline portions 18NC) of a p-type conductivity is to be formed, a dopant gas including at least one p-type dopant, e.g., B, is employed. For example, when boron is the p-type dopant, the dopant gas can be diborane (B₂H₆). In one embodiment, wherein the conductivity type dopant is p-type, the dopant gas may be diborane (B₂H₆) present in a ratio to silane (SiH₄) ranging from 0.01% to 10%. In another embodiment, wherein the conductivity type dopant is p-type, the dopant gas may be diborane (B₂H₆) present in a ratio to silane (SiH₄) ranging from 0.1% to 2%. In yet another embodiment, in which the conductivity type dopant is p-type, the dopant gas for may be trimethylboron (TMB) present in a ratio to silane (SiH₄) ranging from 0.1% to 10%.

In one embodiment of the present disclosure, the pressure for the PECVD process that can be used for epitaxially growing the doped semiconductor material layer (including crystalline portions 18C and non-crystalline portions 18NC) can range from 10 mTorr to 5 Ton, and in one example may be in the range of 250 mtorr to 900 mTorr. The power density for the PECVD process for epitaxially growing the doped semiconductor material layer may range from 1 mW/cm² to 100 mW/cm², and in one example may be in the range of 3 mW/cm² to 10 mW/cm². Further details regarding the epitaxial growth process for forming the doped semiconductor material layer of the present disclosure are described in U.S. Patent Publication No. 2012/0210932, which is owned by the assignee of the present disclosure, and is incorporated herein by reference.

In some embodiments, ammonia (NH₃), nitrous oxide (N₂O) or other gas sources may be used for nitrogen containing layers. Carbon dioxide (CO₂), N₂O or O₂ may be used to provide oxygen for oxygen containing layers. A carrier gas such as hydrogen (H₂), deuterium (D₂) helium (He) or argon (Ar) may be used for any or all of the layers. The carrier gas may be pre-mixed with the gas sources or flowed simultaneously with the gas source at the time of growth.

The doped semiconductor material layer (including crystalline portions 18C and non-crystalline portions 18NC) may comprise a same or different semiconductor material as that of the crystalline semiconductor material 10. In one embodiment, the doped semiconductor material layer (including crystalline portions 18C and non-crystalline portions 18NC) has a formula SiₓGe₁₋ₓ wherein x is 0≦x≦1. As such, the doped semiconductor material layer (including crystalline portions 18C and non-crystalline portions 18NC) may comprise Si (when x is 1), Ge (when x is 0), or a SiGe (when x is other than 1, or 0).

In some embodiments of the present disclosure, the doped semiconductor material layer (including crystalline portions 18C and non-crystalline portions 18NC) may include nitrogen, oxygen, fluorine, deuterium, chlorine or any combination thereof. When present, the concentration of the aforementioned species is from 1 atomic % to 10 atomic percent. Other concentrations that are lesser than, or greater than, the aforementioned concentration range can also be present.

In some embodiments of the present disclosure, the doped semiconductor material layer (including crystalline portions 18C and non-crystalline portions 18NC) can contain C therein. When present, C can be present in a concentration from 0 atomic % to 50 atomic %. In some embodiments, the doped semiconductor material layer (including crystalline portions 18C and non-crystalline portions 18NC) can contain from 0 atomic % to 25 atomic % carbon therein. The carbon impurity can be added by way of either a source gas that includes carbon, or by introducing a carbon source gas into the gas mixture that is employed in the present disclosure for forming the doped semiconductor material layer (including crystalline portions 18C and non-crystalline portions 18NC).

The dopant that is contained within the doped semiconductor material layer (including crystalline portions 18C and non-crystalline portions 18NC) can be a p-type dopant or an n-type dopant. In a Si-containing doped semiconductor material layer (including crystalline portions 18C and non-crystalline portions 18NC) examples of p-type dopants, i.e., impurities, include but are not limited to, boron, aluminum, gallium and indium. In one embodiment, in which the doped semiconductor material layer (including crystalline portions 18C and non-crystalline portions 18NC) includes a p-type dopant, the p-type dopant is present in a concentration ranging from 10¹⁶ atoms/cm³ to 10²¹ atoms/cm³. In another embodiment, in which the doped semiconductor material layer (including crystalline portions 18C and non-crystalline portions 18NC) contains p-type dopant, the p-type dopant is present in a concentration ranging from 10¹⁸ atoms/cm³ to 5×10²⁰ atoms/cm³. In a Si-containing doped semiconductor material layer (including crystalline portions 18C and non-crystalline portions 18NC), examples of n-type dopants, i.e., impurities, include but are not limited to, antimony, arsenic and phosphorous. In one embodiment, in which the doped semiconductor material layer (including crystalline portions 18C and non-crystalline portions 18NC) contains an n-type dopant, the n-type dopant is present in a concentration ranging from 10¹⁶ atoms/cm³ to 10²¹ atoms/cm³. In another embodiment, in which doped semiconductor material layer (including crystalline portions 18C and non-crystalline portions 18NC) contains an n-type dopant, the n-type dopant is present in a concentration ranging from 10¹⁸ atoms/cm³ to 5×10²⁰ atoms/cm³. The dopant within the doped semiconductor material layer (including crystalline portions 18C and non-crystalline portions 18NC) can be uniformly present or present as a gradient.

The thickness of the doped semiconductor material layer (including crystalline portions 18C and non-crystalline portions 18NC) may range from 2 nm to 100 nm. In another embodiment, the thickness of the doped semiconductor material layer (including crystalline portions 18C and non-crystalline portions 18NC) ranges from 5 nm to 15 nm.

Referring now to FIG. 5, there is illustrated the structure of FIG. 4 after removing the doped non-crystalline semiconductor material layer portions 18NC selective to the doped crystalline semiconductor material layer portions 18C and the crystalline semiconductor material of the active device region 10′.

In one embodiment, removing the doped non-crystalline semiconductor material layer portions 18NC selective to the doped crystalline semiconductor material layer portions 18C includes a hydrogen plasma etch. In some embodiments, the hydrogen plasma etch that can be used to remove the doped non-crystalline semiconductor material layer portions 18NC selective to the doped crystalline semiconductor material layer portions 18C can be performed in the same reactor chamber as used to form the doped semiconductor material layer without breaking the vacuum of the chamber; such an etch may be referred to herein as an in-situ hydrogen plasma etch. In other embodiments, the hydrogen plasma etch can be performed in a different reactor chamber as that used to form the doped semiconductor material layer.

The hydrogen plasma etch that can be used to remove the doped non-crystalline semiconductor material layer portions 18NC selective to the doped crystalline semiconductor material layer portions 18C can be performed at a temperature of from room temperature (20° C.) to 500° C. and at a hydrogen pressure from 10 mtorr to 5 torr. In some embodiments, the hydrogen plasma etch is performed at a temperature of from 100° C. to 250° C. and at a hydrogen pressure from 10 mtorr to 1 ton. The hydrogen plasma etch can be performed utilizing one of hydrogen or HCl as a source of the hydrogen plasma. In some embodiments, the etch selectivity for removing the doped non-crystalline semiconductor material layer portions 18NC relative to the doped crystalline semiconductor material layer portion 18C is from 2:1 to 10:1. In some embodiments, the removal of the doped non-crystalline semiconductor material layer portions 18NC relative to the doped crystalline semiconductor material layer portions 18C can be performed using other types of plasmas besides hydrogen plasma including, for example, Cl₂ or Ar.

In this embodiment of the present disclosure and as shown in FIG. 5, the remaining doped crystalline semiconductor material layer portions 18C form the source/drain regions of the thin film transistor. The resultant structure shown in FIG. 5 includes an active device region 10′ comprising a crystalline semiconductor material located on a surface of an insulating substrate 8. The structure further includes a gate structure located on a first surface portion of the active device region 10′, wherein the gate structure comprises, from bottom to top, the hydrogenated non-crystalline semiconductor material layer portion 12, a hydrogenated non-crystalline silicon nitride portion 14 and an electrode material portion 16. The structure further includes a source region located on one side of the gate structure (i.e., 18C located on the left hand side of the gate structure) and in direct contact with a second surface portion of the active device region 10′, and a drain region located on another side of the gate structure (i.e., 18C located on the right hand side of the gate structure) and in direct contact with a third surface portion of the active device region 10, wherein the source region and the drain region each comprise a doped crystalline semiconductor material 18C. As shown, the hydrogenated non-crystalline semiconductor material layer portion 12, the hydrogenated non-crystalline silicon nitride portion 14 and the gate electrode portion 16 have outermost edges that are vertically coincident to each other. In this embodiment (which provides a self-aligned gate structure), the outermost edges of the hydrogenated non-crystalline semiconductor material layer portion 12, the hydrogenated non-crystalline silicon nitride portion 14 and the gate electrode portion 16 do not extend onto an uppermost surface of the source region or onto an uppermost surface of the drain region.

Referring now to FIG. 6, there is illustrated the structure of FIG. 5 after formation of a passivation material 20 thereon. The passivation material 20 that can be employed in the present disclosure may include, for example, hydrogenated non-crystalline silicon nitride or hydrogenated non-crystalline silicon oxide. The hydrogenated non-crystalline silicon nitride passivation material can be formed as described above for the blanket layer of hydrogenated non-crystalline silicon nitride. The hydrogenated non-crystalline silicon oxide can be formed similar to the hydrogenated non-crystalline silicon nitride except that the nitrogen source is replaced with an oxygen source such as, for example, carbon dioxide (CO₂), N₂O or O₂. Other passivation materials which are well known to those skilled in the art may also be employed herein as passivation material 20.

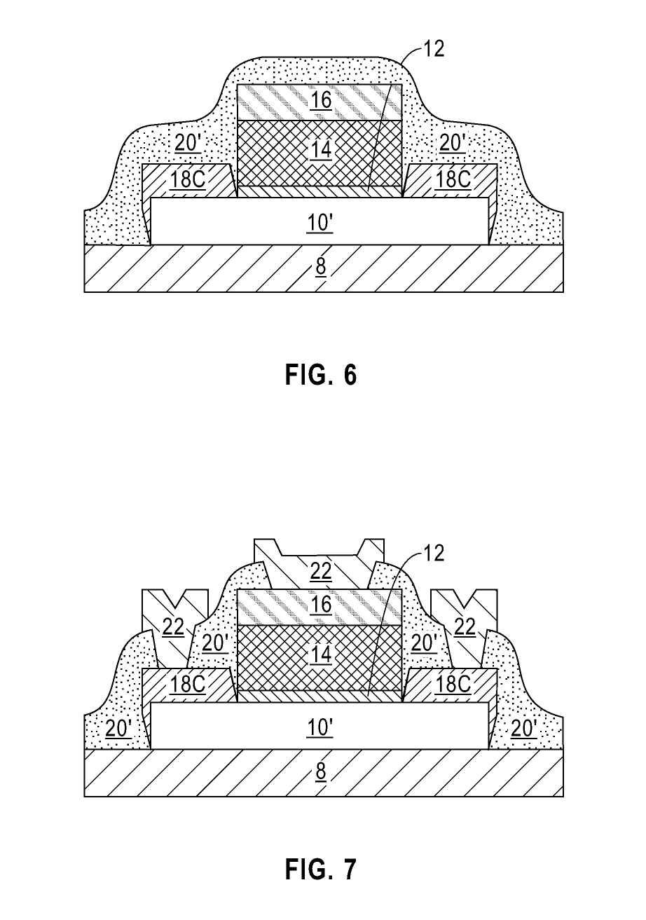

Referring now to FIG. 7, there is illustrated the structure of FIG. 6 after formation of metal contacts 22 within the passivation material 20. As shown in FIG. 7, each metal contact 22 extends entirely through the passivation material 20. Each metal contact also can have a topmost surface that is present above the topmost surface of the passivation material 20. Some of the metal contacts 22 contact an uppermost surface of the source/drain regions 18C, while another of the metal contact 22 may contact an uppermost surface of the electrode material portion 16.

The metal contacts are formed by first providing contact openings within the passivation material utilizing lithography and etching. After providing the contact openings, each contact opening is filled with a conductive material forming metal contacts 22. The metal contacts 22 can include a same or different conductive metal, conductive metal alloy, conductive metal nitride, transparent conductive oxide and/or a conductive metal silicide as that of the electrode material portion 16. Also, the metal contacts 22 can be formed utilizing one on of the deposition techniques mentioned above in forming the electrode material portion 16. Lithography and patterning can follow the deposition of the conductive metal, a conductive metal alloy, a conductive metal nitride, a transparent conductive oxide and/or a conductive metal silicide.

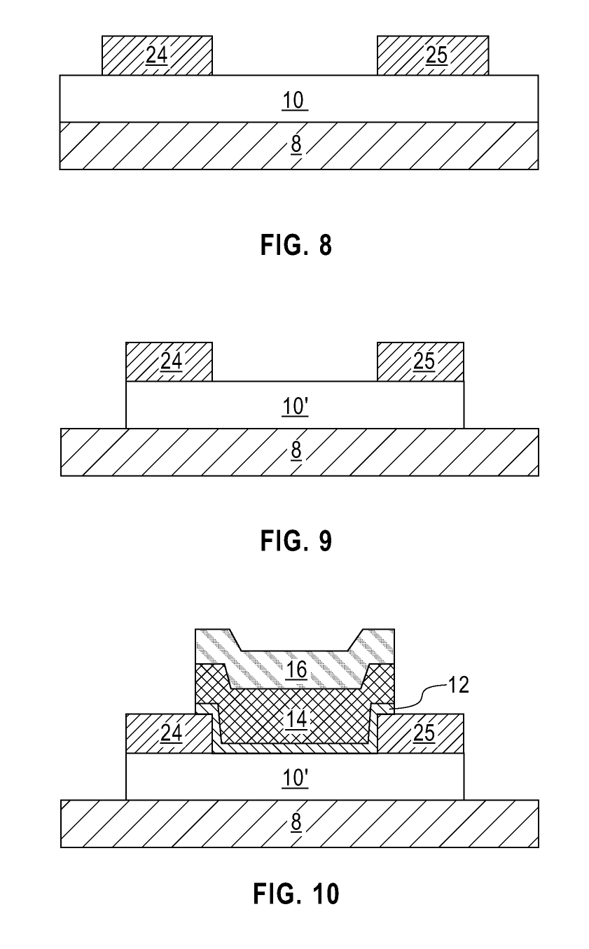

Reference is now made to FIGS. 8-10 which illustrate another embodiment of the present disclosure for forming a thin film transistor comprises a crystalline semiconductor channel. This method of the present disclosure forms thin film transistors that are not self-aligned to the source/drain regions. By “not-self aligned” or “non-self aligned” it is meant that portions of the gate structure extend on uppermost surfaces of the source/drain regions.

Referring first to FIG. 8, there is illustrated the structure of FIG. 1 after forming a source region 24 comprising a doped first crystalline semiconductor material layer portion, and a drain region 25 comprising a doped second crystalline semiconductor material layer portion on a topmost surface of the crystalline semiconductor material in accordance with an embodiment of the present disclosure. As shown, the source region 24 and the drain region 25 are disjoined from each other. The source region 24 comprising the doped first crystalline semiconductor material layer portion and the drain region 25 comprising the doped second crystalline semiconductor material layer portion may by formed by epitaxially growing a blanket layer of doped crystalline semiconductor material on the exposed uppermost surface of the crystalline semiconductor substrate 10. As such, the doped first and second crystalline semiconductor materials have an epitaxial relationship with the surface of the active device region 10′ from which they are formed. After the epitaxial growth of the blanket layer of doped crystalline semiconductor material, lithography and etching can be used to pattern the blanket layer of doped crystalline semiconductor material into source region 24 and drain region 25. The source/drain regions (24, 25) are of a second conductivity type that is opposite from the conductivity type of the crystalline channel (i.e., active device region 10′).

In one embodiment, the blanket layer of doped crystalline semiconductor material used in forming the source region 24 and the drain region 25 can be hydrogenated. In another embodiment, the blanket layer of doped crystalline semiconductor material used in forming the source region 24 and the drain region 25 can be non-hydrogenated. When hydrogenated, the blanket layer of doped crystalline semiconductor material used in forming the source region 24 and the drain region 25 can have a hydrogen content within the range mentioned above for the doped semiconductor material having the crystalline semiconductor portions 18C and the non-crystalline semiconductor portions 18NC.

The blanket layer of doped crystalline semiconductor material used in forming the source region 24 and the drain region 25 can comprise a semiconductor material as described above for the doped semiconductor material having the crystalline semiconductor portions 18C and the non-crystalline semiconductor portions 18NC. The blanket layer of doped crystalline semiconductor material used in forming the source region 24 and the drain region 25 can contain n-type dopants or p-type dopants as also described above for the doped semiconductor material having the crystalline semiconductor portions 18C and the non-crystalline semiconductor portions 18NC. Further, the blanket layer of doped crystalline semiconductor material used in forming the source region 24 and the drain region 25 can have a dopant (p-type or n-type) within the range described above for the doped semiconductor material having the crystalline semiconductor portions 18C and the non-crystalline semiconductor portions 18NC. Also, the blanket layer of doped crystalline semiconductor material used in forming the source region 24 and the drain region 25 can contain C, in amounts also mentioned above for the doped semiconductor material having the crystalline semiconductor portions 18C and the non-crystalline semiconductor portions 18NC. The thickness of the blanket layer of doped crystalline semiconductor material used in forming the source region 24 and the drain region 25 is typically from 2 to 100 nm. Other thicknesses that are greater than or lesser than the aforementioned thickness range can also be used for the blanket layer of doped crystalline semiconductor material used in forming the source region 24 and the drain region 25.

The blanket layer of doped crystalline semiconductor material used in forming the source region 24 and the drain region 25 can be formed utilizing any epitaxial growth process including, but not limited to, PECVD, and HWCVD. In one embodiment, the blanket layer of doped crystalline semiconductor material used in forming the source region 24 and the drain region 25 can be formed utilizing one of the techniques mentioned above for forming the doped semiconductor material having the crystalline semiconductor portions 18C and the non-crystalline semiconductor portions 18NC.

As mentioned above, after epitaxially growing the blanket layer of doped crystalline semiconductor material, the blanket layer of doped crystalline semiconductor material is then patterned by lithography and etching. The etching step can include dry etching (i.e., reactive ion etching, ion beam etching, or plasma etching), wet chemical etching, or a combination thereof. In one embodiment of the present disclosure, a selective etch process (typically a dry etch) is used to pattern the blanket layer of doped crystalline semiconductor material. For example, CF₄, SF₆, SF₆/O₂ or CCl₂F₂/O₂ may be as an etchant to etch exposed portions of the blanket layer of doped crystalline semiconductor material.

In some embodiments, the source region 24 and drain region 25 can be performed after defining the active device region or even after forming the gate structure. In such instances, a doped semiconductor layer comprising crystalline and non-crystalline portions, as mentioned above in conjunction with the structure shown in FIG. 4 is first formed and then the etch mentioned above in conjunction with the structure shown in FIG. 5 can be performed.

Referring now to FIG. 9, there is illustrated the structure of FIG. 8 after defining an active device region 10′ within the crystalline semiconductor material 10. The active device region 10′ can be defined by lithography and etching as mentioned above in conjunction with the structure shown in FIG. 2 of the present disclosure. In some embodiments, the definition of the active device region 10′ can occur after formation of the gate structure.

Referring now to FIG. 10, there is illustrated the structure of FIG. 9 after forming a gate structure on an uppermost surface of the active device region 10′ and an uppermost surface of the source and drain regions (24, 25). The gate structure of this embodiment includes, from bottom to top, a hydrogenated non-crystalline semiconductor material layer portion 12, a hydrogenated non-crystalline silicon nitride portion 14 and an electrode material portion 16. Each of elements 12, 14 and 16 that are used in this embodiment of the present disclosure is the same as mentioned above in conjunction with forming the gate structure shown in FIG. 3 of the present disclosure. Also, the above technique used in forming the gate structure shown in FIG. 3 can also be used here to form the gate structure shown in FIG. 10. The structure shown in FIG. 10 can then be processed, as shown in FIGS. 6 and 7, to include metal contacts 22 within a passivation material 20.

The resultant structure shown in FIG. 10 includes an active device region 10′ comprising a crystalline semiconductor material located on a surface of an insulating substrate 8. The structure further includes a gate structure located on a first surface portion of the active device region 10′, wherein the gate structure comprises, from bottom to top, the hydrogenated non-crystalline semiconductor material layer portion 12, a hydrogenated non-crystalline silicon nitride portion 14 and an electrode material portion 16. The structure further includes a source region 24 located on one side of the gate structure and in direct contact with a second surface portion of the active device region 10′, and a drain region 25 located on another side of the gate structure and in direct contact with a third surface portion of the active device region 10, wherein the source region and the drain region each comprise a doped crystalline semiconductor material. As shown, the hydrogenated non-crystalline semiconductor material layer portion 12, the hydrogenated non-crystalline silicon nitride portion 14 and the gate electrode portion 16 have outermost edges that are vertically coincident to each other. In this embodiment (which provides a non-self-aligned gate structure), the outermost edges of the hydrogenated non-crystalline semiconductor material layer portion 12, the hydrogenated non-crystalline silicon nitride portion 14 and the gate electrode portion 16 extend onto an uppermost surface of the source region and onto an uppermost surface of the drain region. Also, a first portion of the bottommost surface of the hydrogenated non-crystalline semiconductor material layer portion 12 contacts a sidewall surface of the source region 24 on side of the gate structure, and a second portion of the bottommost surface of the hydrogenated non-crystalline semiconductor material layer portion 12 contacts a sidewall surface of the drain region 25 on side of the gate structure; a middle portion of the bottommost surface of hydrogenated non-crystalline semiconductor material layer portion 12 directly contacts the crystalline semiconductor material.

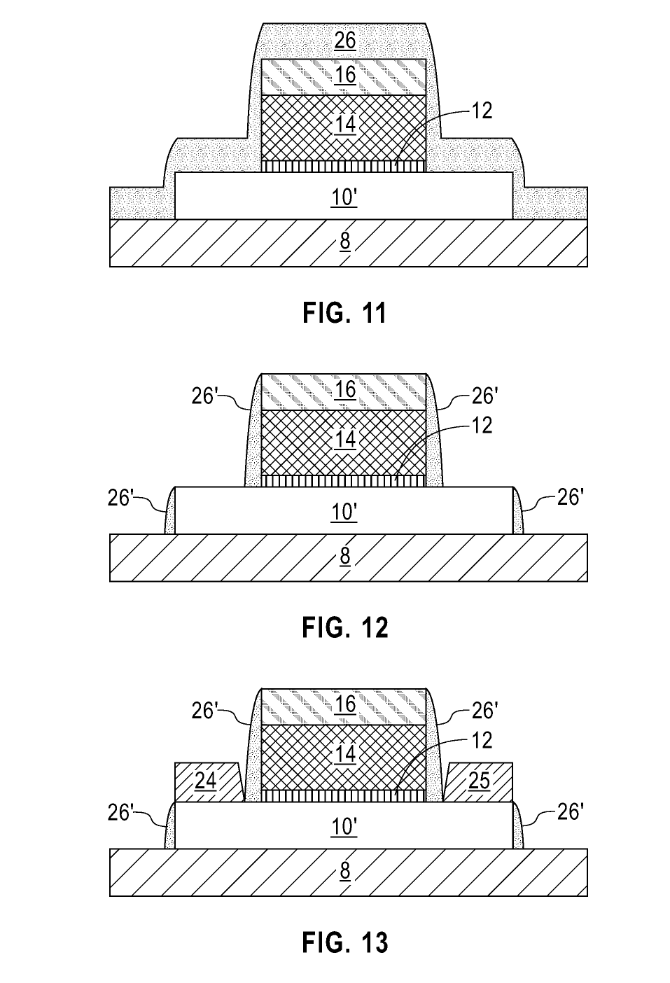

Reference is now made to FIGS. 11-13 which illustrate yet another embodiment of the present disclosure. This embodiment of the present disclosure is similar to the embodiment depicted in FIGS. 1-5, except that after forming the gate structure on the active device region 10′, a dielectric spacer 26′ is formed on exposed sidewalls of the gat structure and, if already formed, sidewalls of the active device region 10′. Specifically, this embodiment of the present disclosure begins by first providing the structure shown in FIG. 3. Next, and as shown in FIG. 11, a dielectric spacer material 26 is formed on all exposed surfaces of the structure shown in FIG. 3.

The dielectric spacer material 26 can be formed by any deposition process including, for example, chemical vapor deposition, and PECVD. In one embodiment, the dielectric spacer material 26 can be formed using well known silicon sources, if applicable; oxygen sources, and, if applicable, nitrogen sources.

The dielectric spacer material 26 may include any dielectric spacer material including for example, semiconductor oxide, semiconductor nitrides, and/or semiconductor oxynitrides. In one embodiment, the dielectric spacer material 26 can be comprised of a hydrogenated non-crystalline silicon nitride and/or hydrogenated non-crystalline silicon oxide.

Referring now to FIG. 12, there is illustrated the structure of FIG. 11 after etching the dielectric spacer material 26 forming dielectric spacers 26′. The etching of the dielectric spacer material 26 may include any isotropic etch process. As shown, dielectric spacers 26′ are located on sidewall surfaces of the gate structure as well as sidewall surfaces of the active device region 10′. The dielectric spacer 26′ that is located on the sidewall surfaces of the gate structure has a base that is located on a surface of the active device region 10′ (or if the active device region is not yet defined, the base would be located on the surface of the crystalline semiconductor material 10). The dielectric spacer 26′ that can be formed on the sidewall surfaces of the active device region 10′ have a base located on a surface of the insulating substrate 8. In each instance, the width of the dielectric spacer at the base is thicker than a width of a topmost portion of the dielectric spacer 26′. In some embodiments, and if not previously formed, the dielectric spacers 26′ can be omitted from the sidewall surfaces of the active device region 10′. In some instances, the dielectric spacers 26′ can reduce the undesired leakage path between the source/drain regions and the gate structure.

Referring now to FIG. 13, there is illustrated the structure of FIG. 12 after forming source region 25 and drain region 26. In this embodiment, the source/drain regions 24/25 can be formed using the technique and materials mentioned above in regard to forming source/drain regions within FIGS. 4 and 5 of the first embodiment of the present disclosure. Since the dielectric spacer 26′ is insulating, the doped semiconductor layer grown on the dielectric spacers 26′ are non-crystalline, and can be selectively etched away, for example using a hydrogen plasma. The structure shown in FIG. 13 can then be processed, as shown in FIGS. 6 and 7, to include metal contacts 22 within a passivation material 20.

It is noted that within any of the embodiments mentioned above, a plurality of gate structures can be formed on a same or different active device region of crystalline semiconductor material utilizing one of the techniques mentioned above. Also, the order of the various processes steps can be changed as would be apparent to one skilled in the art.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A semiconductor structure comprising:
an active device region comprising a crystalline semiconductor material located on a surface of an insulating substrate; and
a gate structure located on a first surface portion of the active device region, wherein said gate structure comprises, from bottom to top, a hydrogenated non-crystalline semiconductor material layer portion, a hydrogenated non-crystalline silicon nitride portion and an electrode material portion.

2. The semiconductor structure of claim 1, further comprising a source region located on one side of the gate structure and in direct contact with a second surface portion of the active device region, and a drain region located on another side of the gate structure and in direct contact with a third surface portion of the active device region, wherein said source region and said drain region each comprise a doped crystalline semiconductor material.

3. The semiconductor structure of claim 2, wherein said active device region comprising the crystalline semiconductor material is of a first conductivity type and said doped crystalline semiconductor material of said source region and said drain region are of a second conductivity type that is opposite from the first conductivity type.

4. The semiconductor structure of claim 2, wherein said hydrogenated non-crystalline semiconductor material layer portion, said hydrogenated non-crystalline silicon nitride portion and said gate electrode portion have outermost edges that are vertically coincident to each other.

5. The semiconductor structure of claim 2, wherein said doped crystalline semiconductor material of said source region and said drain region is hydrogenated.

6. The semiconductor structure of claim 4, wherein said outermost edges of said hydrogenated non-crystalline semiconductor material layer portion, said hydrogenated non-crystalline silicon nitride portion and said gate electrode portion do not extend onto an uppermost surface of the source region or onto an uppermost surface of the drain region.

7. The semiconductor structure of claim 4, wherein said outermost edges of said hydrogenated non-crystalline semiconductor material layer portion, said hydrogenated non-crystalline silicon nitride portion and said gate electrode portion extend onto an uppermost surface of the source region and onto an uppermost surface of the drain region.

8. The semiconductor structure of claim 7, wherein a first portion of bottommost surface of the hydrogenated non-crystalline semiconductor material layer portion directly contacts a sidewall surface of the source region and a second portion of the bottommost surface portion of the hydrogenated non-crystalline semiconductor material layer portion directly contacts a sidewall surface of the drain region.

9. The semiconductor structure of claim 2, further comprising a first dielectric spacer positioned between the gate structure and the source region and a second dielectric spacer positioned between the gate structure and the drain region, wherein said first dielectric spacer and said second dielectric spacer each have a base that is in direct contact with a surface portion of the active device region.

10. The semiconductor structure of claim 2, wherein said active device region does not span the entirety of the insulating substrate.

11. The semiconductor structure of claim 10, wherein a dielectric spacer is present on each sidewall surface of the active device region, wherein each dielectric spacer present on the sidewall surface of the active device region has a base in direct contact with a surface portion of the insulating substrate.

12. The semiconductor structure of claim 10, wherein a portion of said source region and a portion of the drain region each extends onto a sidewall surface of the active device region.

13. The semiconductor structure of claim 2, further comprising a passivation material having a first metal contact that extends to an uppermost surface of the source region, a second metal contact that extends to an uppermost surface of the electrode material portion, and a third metal contact that extends to an uppermost surface of the drain region.

14. The semiconductor structure of claim 1, wherein said hydrogenated non-crystalline semiconductor material layer portion comprises hydrogenated amorphous silicon.

15. The semiconductor structure of claim 1, wherein said hydrogenated non-crystalline semiconductor material layer portion is optionally doped.

16. The semiconductor structure of claim 2, wherein said doped crystalline semiconductor material is selected from Si, SiGe and Ge.

17. A method of forming a semiconductor structure comprising:
forming a gate structure on a first surface portion of a crystalline semiconductor material, wherein the gate structure comprises, from bottom to top, a hydrogenated non-crystalline semiconductor material layer portion, a hydrogenated non-crystalline silicon nitride portion and an electrode material portion; and
epitaxially growing a first doped crystalline semiconductor material portion on one side of the gate structure and in direct contact with a second surface portion of the crystalline semiconductor material, and a second doped crystalline semiconductor material portion on another side of the gate structure and in direct contact with a third surface portion of the crystalline semiconductor material.

18. The method of claim 17, wherein said crystalline semiconductor material is located on a surface of an insulating substrate, and wherein prior to forming the gate structure, the crystalline semiconductor material is patterned into an active device region.

19. The method of claim 18, wherein said forming the gate structure comprises depositing a blanket layer of hydrogenated non-crystalline semiconductor material and a blanket layer of hydrogenated non-crystalline silicon nitride, forming a mask on the blanket layer of hydrogenated non-crystalline silicon nitride and etching exposed portions of the blanket layer of hydrogenated non-crystalline semiconductor material and exposed portions of the blanket layer of hydrogenated non-crystalline silicon nitride.

20. The method of claim 18, wherein said epitaxially growing the first doped crystalline semiconductor material portion and the second doped crystalline semiconductor material portion is performed simultaneously at a temperature of less than 500° C.

21. The method of claim 18, further comprising forming dielectric spacers on exposed sidewall surfaces of the gate structure prior to epitaxially growing the first and second doped crystalline semiconductor material portions.

22. A method of forming a semiconductor structure comprising:
forming a source region comprising an epitaxial first doped crystalline semiconductor material portion on a surface portion of a crystalline semiconductor material, and a drain region comprising an epitaxial second doped crystalline semiconductor material portion on another surface portion of the crystalline semiconductor material, wherein the source region and the drain region are disjoined from each other; and
forming a gate structure on a further surface portion of a crystalline semiconductor material and between the source region and the drain region, wherein the gate structure comprises, from bottom to top, a hydrogenated non-crystalline semiconductor material layer portion, a hydrogenated non-crystalline silicon nitride portion and an electrode material portion.

23. The method of claim 22, wherein said crystalline semiconductor material is located on a surface of an insulating substrate, and wherein prior to forming the source and drain regions, the crystalline semiconductor material is patterned into an active device region.

24. The method of claim 22, wherein said forming the gate structure comprises depositing a blanket layer of hydrogenated non-crystalline semiconductor material and a blanket layer of hydrogenated non-crystalline silicon nitride, forming a mask on the blanket layer of hydrogenated non-crystalline silicon nitride and etching exposed portions of the blanket layer of hydrogenated non-crystalline silicon nitride and exposed portions of the blanket layer of hydrogenated non-crystalline semiconductor material.

25. The method of claim 22, wherein forming the source and drain regions comprises epitaxially growing a blanket layer of doped semiconductor material on the crystalline semiconductor material at a temperature of less than 500° C. and patterning the blanket layer of doped semiconductor material by lithography and etching.
